(19) United States
(12) Patent Application Publication
(10) Pub. No.: US 2025/0253301 A1
(43) Pub. Date: Aug. 7, 2025

(54) SEMICONDUCTOR DEVICE

(71) Applicant: Samsung Electronics Co., Ltd., Suwon-si (KR)

(72) Inventor: Jongpil Son, Suwon-si (KR)

(21) Appl. No.: 18/930,045

(22) Filed: Oct. 29, 2024

(30) Foreign Application Priority Data
Feb. 2, 2024 (KR) 10-2024-0016763

(51) Int. Cl. H01L 25/18; H01L 23/48; H01L 29/423; H10B 80/00

(52) U.S. Cl. CPC H01L 25/18; H01L 23/481; H10D 64/519; H01L 2225/06513; H01L 2225/06517; H01L 2225/06541; H10B 80/00

(57) ABSTRACT

A semiconductor device may include a plurality of vertically stacked dies, each of the dies including a semiconductor substrate, upper pads on an upper surface of the semiconductor substrate, lower pads on a lower surface of the semiconductor substrate, through silicon vias extending in the semiconductor substrate and electrically connected to the upper pads and the lower pads, and a through silicon via (TSV) driver on the semiconductor substrate and configured to control the through silicon vias. The TSV driver may include at least one transistor including a gate electrode that has a closed loop shape when viewed in a plan view.

### CROSS-REFERENCE TO RELATED APPLICATIONS

This U.S. non-provisional patent application claims priority under 35 U.S.C. § 119 to Korean Patent Application No. 10-2024-0016763 filed on Feb. 2, 2024, in the Korean Intellectual Property Office, the entire contents of which are hereby incorporated by reference.

### BACKGROUND OF THE INVENTION

This disclosure relates to a semiconductor device including vertically stacked dies.

In recent years, the use of electronic devices such as smart phones, tablet PCs, digital cameras, MP3 players, and personal digital assistants (PDAs) has rapidly increased. Such electronic devices may have a high-speed processor to accommodate multimedia processing and an increase in throughput of various types of data, along with various application programs that are executed in the electronic devices.

The electronic devices include semiconductor devices such as working memories (e.g., DRAM), nonvolatile memories, and application processors (AP) to drive various application programs. As the amount of data to be processed by the electronic devices increases, a memory device having high capacity and high bandwidth may be helpful. In particular, to process data at high speed, the use of memory devices that provide wide input/output of a multi-channel interface method such as high bandwidth memory (HBM) has increased.

### SUMMARY OF THE INVENTION

Some example embodiments of the inventive concepts provide a semiconductor device with improved integration and operating characteristics.

The objects of the inventive concepts are not limited to the problems mentioned above, and other objects not mentioned will be clearly understood by those skilled in the art from the description below.

According to some embodiments of the inventive concepts, a semiconductor device may include a plurality of vertically stacked dies, each of the dies including a semiconductor substrate, upper pads on an upper surface of the semiconductor substrate, lower pads on a lower surface of the semiconductor substrate, through silicon vias extending in the semiconductor substrate and electrically connected to the upper pads and the lower pads, and a through silicon via (TSV) driver on the semiconductor substrate and configured to control the through silicon vias, wherein the TSV driver includes at least one transistor including a gate electrode that has a closed loop shape when viewed in a plan view.

According to some embodiments of the inventive concepts, a semiconductor device may include a plurality of vertically stacked dies, each of the dies including a semiconductor substrate, upper pads on an upper surface of the semiconductor substrate, lower pads on a lower surface of the semiconductor substrate, through silicon vias extending in the semiconductor substrate and electrically connected to the upper pads and the lower pads, and a through silicon via (TSV) driver on the semiconductor substrate and configured to control the through silicon vias, wherein the TSV driver includes a transistor including a first gate electrode and a second gate electrode that each have a closed loop shape when viewed in a plan view, and wherein the second gate electrode surrounds the first gate electrode when viewed in a plan view.

According to some embodiments of the inventive concepts, a semiconductor device may include a buffer die including first through silicon vias and first through silicon via (TSV) drivers that are configured to control the first through silicon vias, and a plurality of core dies vertically stacked on the buffer die, each of the core dies including second through silicon vias electrically connected to the first through silicon vias and second TSV drivers configured to control the second through silicon vias, wherein each of the first and second TSV drivers includes a plurality of transistors each including a gate electrode that has a closed loop shape when viewed in a plan view.

According to some embodiments of the inventive concepts, a semiconductor device may include vertically stacked dies, each of the dies including a semiconductor substrate, a plurality of gate electrodes on the semiconductor substrate and each having a closed loop shape when viewed in a plan view, first impurity regions in the semiconductor substrate and respectively surrounded by the gate electrodes when viewed in a plan view, second impurity regions in the semiconductor substrate and surrounding the gate electrodes when viewed in a plan view, and through silicon vias extending in the semiconductor substrate and electrically connected to the first impurity regions.

Specific details of other embodiments are included in the detailed description and drawings.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a perspective view of a semiconductor device according to embodiments of the inventive concepts.

FIGS. 2 and 3 are diagrams schematically showing a configuration of a semiconductor device according to embodiments of the inventive concepts.

FIG. 4 is a diagram of a semiconductor device in a semiconductor package according to embodiments of the inventive concepts.

FIG. 5 is a schematic circuit diagram showing a portion of a semiconductor device according to embodiments of the inventive concepts.

FIGS. 6A and 6B are plan views showing a portion of a semiconductor device according to embodiments of the inventive concepts.

FIG. 7 is a cross-sectional view taken along lines I-I′ and II-II′ of FIG. 6A.

FIG. 8 is a diagram showing a portion of a semiconductor device according to embodiments of the inventive concepts.

FIGS. 9A, 9B, 9C, and 9D are plan views showing a portion of a semiconductor device according to embodiments of the inventive concepts.

FIGS. 10A and 10B are plan views showing a portion of a semiconductor device according to embodiments of the inventive concepts.

FIGS. 11A and 11B are plan views showing a portion of a semiconductor device according to embodiments of the inventive concepts.

FIG. 12 is a cross-sectional view taken along line III-III′ of FIG. 11A.

FIG. 13 is a diagram illustrating a semiconductor package including a semiconductor device according to embodiments of the inventive concepts.

FIG. 14 is a cross-sectional view of a semiconductor package including a semiconductor device according to embodiments of the inventive concepts.

### DETAILED DESCRIPTION

Hereinafter, a semiconductor device according to embodiments of the inventive concepts will be described in detail with reference to the drawings.

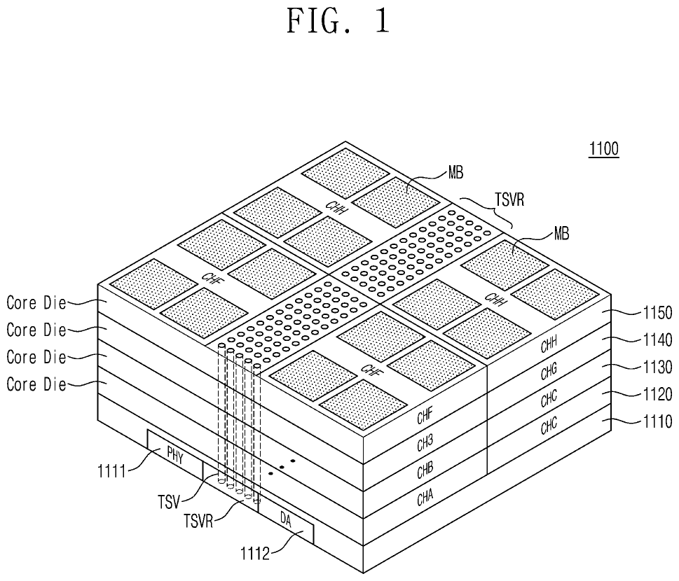

FIG. 1 is a perspective view of a semiconductor device according to embodiments of the inventive concepts.

Referring to FIG. 1, a semiconductor device 1100 may include a buffer die 1110 and a plurality of core dies 1120 to 1150 vertically stacked on the buffer die 1110. For example, the buffer die 1110 may also be referred to as an interface die, base die, logic die, or master die, and each of the core dies 1120 to 1150 may also be referred to as a memory die, or slave die.

The buffer die 1110 and the core dies 1120 to 1150 may be stacked and electrically connected by way of through silicon vias TSV. Accordingly, the semiconductor device 1100 may have a three-dimensional (3D) memory structure in which a plurality of dies 1110 to 1150 are stacked. For example, the semiconductor device 1100 may be configured based on high bandwidth memory (HBM) or hybrid memory cube (HMC) standards.

The buffer die 1110 may receive commands, addresses, and data from a memory controller, and may provide the received commands, addresses, and data to the core dies 1120 to 1150. The buffer die 1110 may buffer commands, addresses, and data, and thus the memory controller may drive a load of the buffer die 1110 in response to the commands, addresses, and data to interface with the core dies 1120 to 1150.

The buffer die 1110 may include a through silicon via (TSV) region TSVR, a physical region 1111, and a direct access region 1112.

The TSV region TSVR may be a region provided with through silicon vias TSV that vertically penetrate the buffer die 1110. The buffer die 1110 may transmit and receive signals and/or data with the core dies 1120 to 1150 through the through silicon vias TSV.

A physical layer PHY including interface circuits for communication with an external host device may be provided in the physical region 1111. Signals and/or data received through the physical layer PHY of the buffer die 1110 may be transmitted to the core dies 1120 to 1150 through the through silicon vias TSV.

The direct access region 1112 may be a region where input/output related circuits for direct interface with an external device (e.g., a test device, not shown) are provided. The direct access region 1112 may include conductive means (e.g., ports or pins) that may communicate directly with an external test device. Various signals provided from the external test device may be provided to the core dies 1120 to 1150 through the direct access region 1112 and the TSV region TSVR.

The core dies 1120 to 1150 may be vertically stacked on the buffer die 1110. FIG. 1 shows that the semiconductor device 1100 includes four core dies 1120 to 1150, but the number of core dies may be variously changed. For example, the semiconductor device 1100 may include 8, 12, or 16 core dies.

Each of the core dies 1120 to 1150 may include through silicon vias TSV and may be electrically connected to the buffer die 1110 through the through silicon vias TSV. Each of the core dies 1120 to 1150 may include a memory cell array, a column decoder, a row decoder, a sense amplifier, a write driver, and an input/output buffer.

Each of the core dies 1120 to 1150 may include two or more channels. When each core die 1120 to 1150 includes two channels, the semiconductor device 1100 may have first to eighth channels CHA to CHH, as shown in FIG. 1.

The semiconductor device 1100 may support a plurality of functionally independent channels CHA to CHH (or vaults). When each of the channels CHA to CHH supports 128 data (DQ) transmission paths, the semiconductor device 1100 may support 1024 data transmission paths. However, the inventive concepts are not limited thereto, and the semiconductor device 1100 may support 1024 or more data transmission paths and 8 or more channels (e.g., 16 channels). When the semiconductor device 1100 supports 16 channels, each of the channels may support 64 data transmission paths.

Each of the channels CHA to CHH may include a plurality of memory banks MB. Each of the memory banks MB may include memory cells connected to word lines and bit lines, a row decoder, a column decoder, and a sense amplifier. For example, each of the channels CHA to CHH may include 8 memory banks MB. However, the inventive concepts are not limited thereto, and each of the channels CHA to CHH may include 8 or more memory banks MB. As used herein, “an element A connected to an element B” (or similar language) means that the element A is physically and/or electrically connected to the element B.

Each of the core dies 1120 to 1150 may include a plurality of through silicon vias TSV, and through silicon vias TSV corresponding to each channel may be disposed in the TSV region TSVR. The through silicon vias TSV may be connected to TSV driver circuits for data input and output in each channel.

Each of the core dies 1120 to 1150 may transmit and receive signals and/or data with the buffer die 1110 and other core dies 1120 to 1150 through the through silicon vias TSV. In this case, signals and/or data may be transmitted and received independently through corresponding through silicon vias TSV for each channel. For example, when an external host device transmits a command and an address to the first channel CHA to access the memory cell of the first core die 1120, the buffer die 1110 may transmit control signals to the first core die 1120 to access the memory cell of the first channel CHA through the through silicon vias TSV corresponding to the first channel CHA. The control signals may be transmitted to the first core die 1120 through the corresponding through silicon vias TSV to access the memory cell of the first channel CHA.

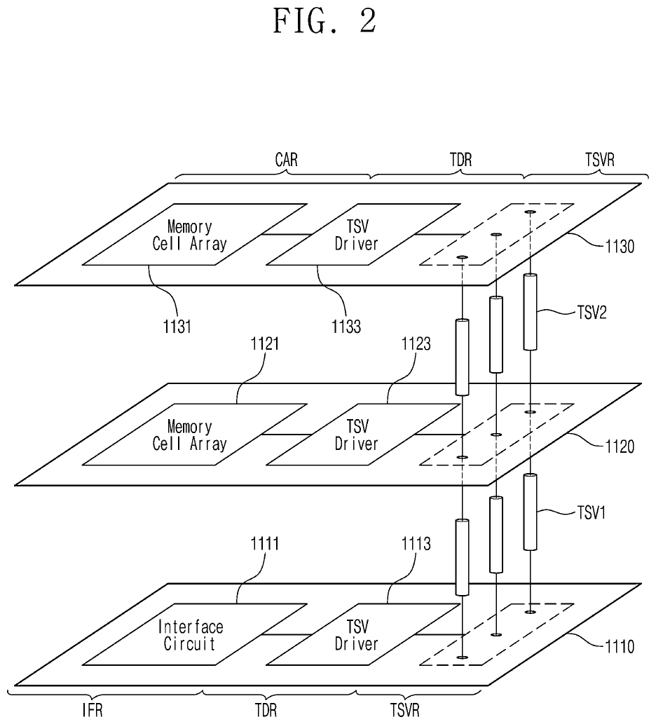

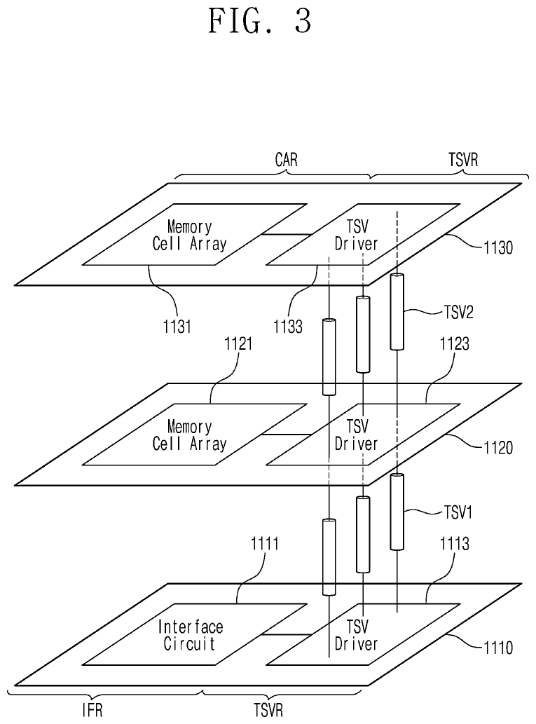

FIGS. 2 and 3 are diagrams schematically showing the configuration of a semiconductor device according to embodiments of the inventive concepts.

Referring to FIG. 2, as described above, the semiconductor device may include a buffer die 1110 and core dies 1120 and 1130 stacked on the buffer die 1110. Although two core dies 1120 and 1130 are shown in FIGS. 2 and 3, as previously described, the semiconductor device may include 4, 8, 12, 16 or more core dies vertically stacked.

The buffer die 1110 may include a TSV region TSVR, a TSV driver region TDR (i.e., a driver circuit region), and an interface region IFR.

First through silicon vias TSV1 penetrating (i.e., extending in) the buffer die 1110 may be provided in the TSV region TSVR of the buffer die 1110.

A first TSV driver circuit 1113 including buffer circuits for transmitting and receiving signals provided to the core dies 1120 and 1130 may be provided in the TSV driver region TDR.

An interface circuit 1111 that connects the semiconductor device to the memory controller may be provided in the interface region IFR. The interface circuit 1111 may include a sense amplifier and a flip-flop. The sense amplifier may be a device that amplifies a data signal. The flip-flop may be a device that holds or stores data signals. The interface circuit 1111 may transmit the data signal received from the electrically connected first TSV driver circuit 1113 to another electronic device. Additionally, the interface circuit 1111 may output a data signal received from the memory controller to the first TSV driver circuit 1113.

Each of the core dies 1120 and 1130 may include a TSV region TSVR, a TSV driver region TDR (i.e., a driver circuit region), and a cell array region CAR.

Second through silicon vias TSV2 penetrating the core dies 1120 and 1130 may be provided in the TSV region TSVR of each of the core dies 1120 and 1130. A command decoder, a data input/output circuit, and a memory cell array 1121 or 1131 may be provided in the cell array region CAR of each of the core dies 1120 and 1130.

Each TSV driver region TDR of the core dies 1120 and 1130 may include second TSV driver circuits 1123 and 1133 that transmit and receive signals provided to the core dies 1120 and 1130. The second TSV driver circuits 1123 and 1133 may input and output data from the through silicon vias TSV2 in the TSV region TSVR. The second TSV driver circuits 1123 and 1133 may include buffer circuits that transmit and receive signals from the buffer die 1110.

Referring to FIG. 3, the buffer die 1110 may include a TSV region TSVR and an interface region IFR, and each of the core dies 1120 and 1130 may include a TSV region TSVR and a cell array region CAR.

Through silicon vias TSV1 and TSV2 and first or second TSV driver circuits 1113, 1123, or 1133 that transmit and receive data through the through silicon vias TSV1 and TSV2 may be provided in the TSV region TSVR of each die 1110, 1120, and 1130.

The first and second through silicon vias TSV1 and TSV2 and the first and second TSV driver circuits 1113, 1123, and 1133 may be provided in the TSV region TSVR, thereby reducing integration and a size of the semiconductor device.

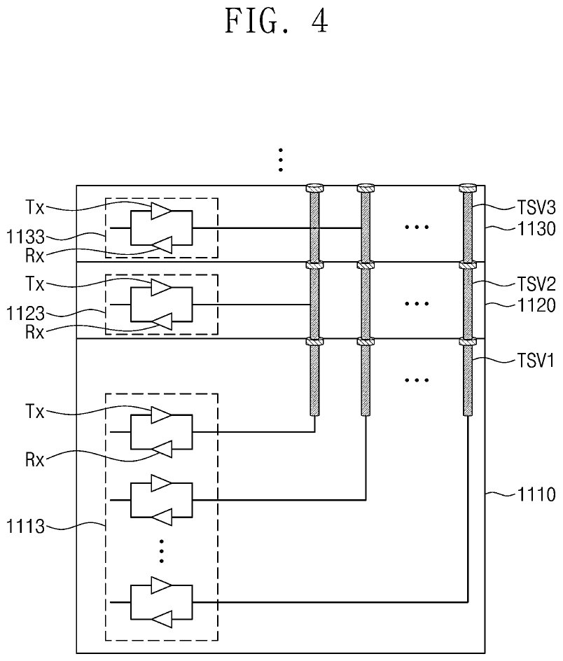

FIG. 4 is a diagram of a semiconductor device in a semiconductor package according to embodiments of the inventive concepts.

Referring to FIG. 4, the buffer die 1110 may include the first TSV driver circuit 1113, as described above. The first TSV driver circuit 1113 may include a plurality of buffer circuits, and each buffer circuit may include a transmitter Tx and a receiver Rx. Each buffer circuit may buffer an input signal and output the buffered signal as an output signal.

In the buffer die 1110, each of the plurality of first through silicon vias TSV1 may be connected to an output terminal of one transmitter Tx and an input terminal of one receiver Rx. That is, one transmitter Tx and one receiver Rx may share one first through silicon via TSV1.

The transmitter Tx may be driven based on at least one of power or ground voltages, and the data signal received from the interface circuit may be output to the second TSV driver circuits 1123 and 1133 of the core dies 1120 and 1130 through the corresponding first through silicon vias TSV1. The receiver Rx may be driven based on at least one of power or ground voltages, the data signals may be received from the second TSV driver circuits 1123 and 1133 through the corresponding first through silicon vias TSV1, and data signals may be output to the interface circuit.

Each of the core dies 1120 and 1130 may include second TSV driver circuits 1123 or 1133, as previously described with reference to FIGS. 2 and 3. Each of the second TSV driver circuits 1123 and 1133 may include a transmitter Tx and a receiver Rx, and each of the through silicon vias TSV (i.e., second and third through silicon vias TSV2 and TSV3) may be connected to an output terminal of one transmitter Tx and an input terminal of one receiver Rx.

The transmitter Tx may be driven based on at least one of power or ground voltages, and the data signal received from the memory cell array may be output to the first TSV driver circuit 1113 through the corresponding second through silicon vias TSV2. The receiver Rx may be driven based on at least one of power or ground voltages, the data signal may be received from the first TSV driver circuit 1113 through the corresponding second through silicon vias TSV2, and the data signals may be output to a memory cell array.

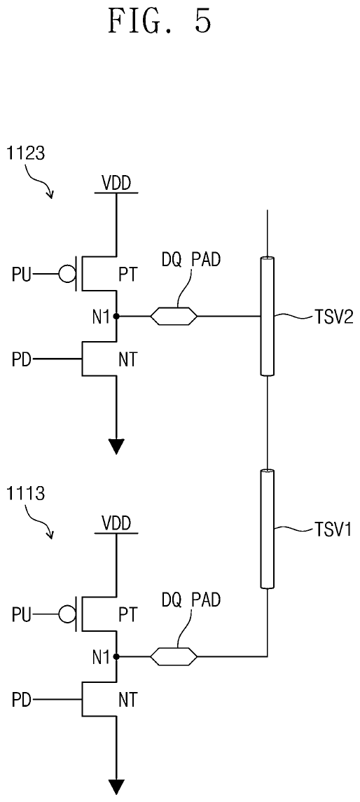

FIG. 5 is a schematic circuit diagram showing a portion of a semiconductor device according to embodiments of the inventive concepts.

Referring to FIGS. 4 and 5, the buffer die 1110 and the core dies 1120 and 1130 may include first and second TSV driver circuits 1113, 1123 and 1133, respectively, as described above. Each of the first and second TSV driver circuits 1113, 1123, and 1133 may include a first transistor PT and a second transistor NT.

The first transistor PT may be connected between a power supply voltage VDD and a first node N1, and may operate in response to a pull-up signal PU. The first node N1 may be connected to a DQ pad, and a data signal may be generated from the DQ pad. The DQ pad may be data/command input/output pads provided on the buffer die 1110 and the core dies 1120 and 1130. When the first transistor PT is turned on in response to the pull-up signal PU, the power supply voltage VDD may be supplied to the first node N1. In this case, the second transistor NT may be turned off.

The second transistor NT may be connected between the first node N1 and a ground voltage (i.e., VSS) and may operate in response to a pull-down signal PD. The first node N1 may be connected to the DQ pad. When the second transistor NT is turned on in response to the pull-down signal PD, the ground voltage (VSS) may be supplied to the first node N1. In this case, the first transistor PT may be turned off.

The DQ pad, which is the output terminal of the first TSV driver circuit 1113, may be connected to the first through silicon via TSV1. The DQ pad, which is the output terminal of the second TSV driver circuit 1123, may be connected to the second through silicon via TSV2.

In embodiments, the transistors NT and PT constituting buffer circuits or latch circuits of the first and second driver circuits 1113, 1123, and 1133 may include gate electrodes in a form of a closed curve. This is explained in more detail with reference to the drawings below.

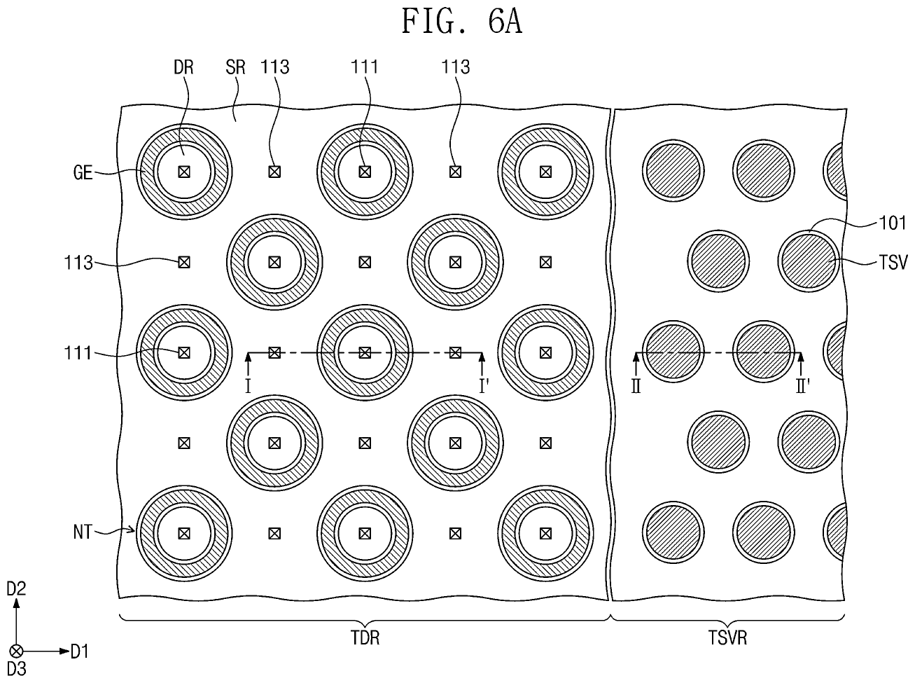

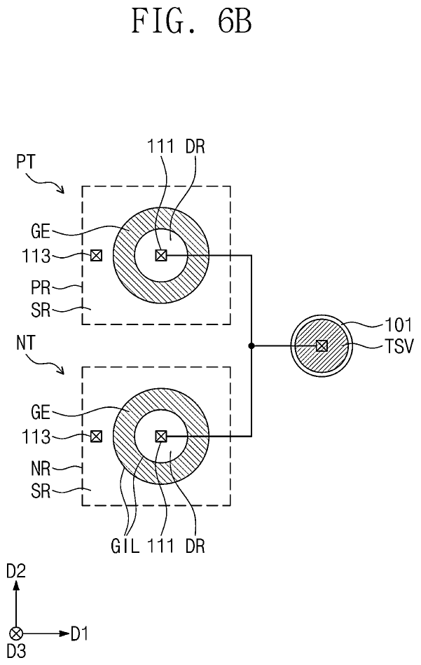

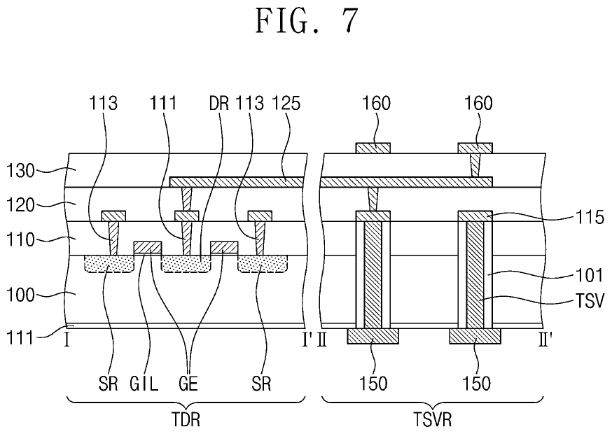

FIGS. 6A and 6B are plan views showing a portion of each die of a semiconductor device according to embodiments of the inventive concepts. FIG. 7 is a cross-sectional view taken along lines I-I′ and II-II′ of FIG. 6A.

Referring to FIGS. 6A, 6B, and 7, each die of the semiconductor device may include a semiconductor substrate 100, lower and upper pads 150 and 160, through silicon vias TSV, and a TSV driver. The TSV driver may include a plurality of transistors PT and NT, and at least some of the plurality of transistors PT and NT may include a closed curve-shaped gate electrode GE. That is, at least some of the plurality of transistors PT and NT may include a gate electrode GE that has a closed curve (i.e., loop) shape. As used herein, a closed curve shape may refer to a geometric figure that is formed by a continuous curve and/or line segments, where the starting point and ending point substantially coincide, forming a closed loop. It will be understood that a closed curve shape may be a shape that has a continuous curve forming a closed loop (e.g., a circle, an ellipse, and the like) but is not necessarily limited thereto. For example, a closed curve shape may also be a shape that includes line segments forming a continuous, closed loop (e.g., a square, a hexagon, an octagon, and the like). As used herein, a closed curve shape may also be referred to as a closed shape.

Specifically, the semiconductor substrate 100 may be one of a material with semiconductor properties (e.g., a silicon wafer), an insulating material (e.g., glass), a semiconductor covered with an insulating material, or a conductor. For example, the semiconductor substrate 100 may be a silicon wafer having a first conductivity type (e.g., p-type).

The semiconductor substrate 100 may have a first surface and a second surface that face each other. The semiconductor substrate 100 may include a driver circuit region TDR and a TSV region TSVR.

In the driver circuit region TDR, transistors PT and NT constituting the TSV driver may be integrated on the first surface of the semiconductor substrate 100. The driver circuit region TDR may include an NMOS region NR and a PMOS region PR.

Each of the transistors PT and NT may include a closed curve-shaped gate electrode GE, a first impurity region DR (or drain region), and a second impurity region SR (or source region). For example, the gate electrode GE may have a closed loop shape when viewed in a plan view.

The gate electrode GE may have a closed curve shape (i.e., a ring shape or a donut shape) when viewed in a plan view. As an example, the gate electrode GE may have a ring donut shape when viewed in a plan view. An opening (e.g., an interior void), which is an empty space, may be defined inside the gate electrode GE (e.g., when viewed in a plan view).

The gate electrode GE may include polysilicon or a metal material doped with impurities. A gate insulating layer GIL may be interposed between the gate electrode GE and the semiconductor substrate 100.

In embodiments, the gate electrodes GE of the transistors PT and NT may be spaced apart from each other in a first direction D1 and a second direction D2 intersecting the first direction D1 on the semiconductor substrate 100. For example, the gate electrodes GE of the transistors PT and NT may be arranged two-dimensionally. The first direction D1 and the second direction D2 may be parallel to the first surface of the semiconductor substrate 100. A third direction D3 may intersect the first direction DI and the second direction D2, and the third direction D3 may be perpendicular to the first surface of the semiconductor substrate 100. Some of the gate electrodes GE may be provided in the NMOS region NR, and the others may be provided in the PMOS region PR.

The first and second impurity regions DR and SR may be provided in the semiconductor substrate 100 and may include impurities of a second conductivity type (e.g., n-type) opposite to that of the semiconductor substrate 100.

The first impurity region DR may be provided inside the gate electrode GE, and when viewed in a plan view, the gate electrode GE may surround the first impurity region DR. For example, the gate electrode GE may have a closed loop shape when viewed in a plan view. When the semiconductor device operates, a data/command signal may be output from the first impurity region DR.

The second impurity region SR may be provided outside the gate electrode GE and may surround the gate electrode GE when viewed in a plan view. The second impurity region SR disposed outside the gate electrode GE may have a larger region (i.e., a larger area) than the first impurity region DR. Additionally, the second impurity region SR may be provided between adjacent gate electrodes GE. Accordingly, the adjacent transistors PT and NT may share the second impurity region SR.

The transistors NT and PT may be electrically connected to the through silicon vias TSV through wiring patterns 115 and 125. As used herein, the wiring patterns 115 and 125 may also be referred to as conductive lines.

In more detail, a first interlayer insulating layer 110 may be on (e.g., may cover) the transistors NT and PT on the first surface of the semiconductor substrate 100.

First contact plugs 111 may penetrate the first interlayer insulating layer 110 and may be connected to the first impurity regions DR, respectively. Second contact plugs 113 may penetrate the first interlayer insulating layer 110 and may be connected to the second impurity regions SR, respectively.

The through silicon vias TSV may penetrate the first interlayer insulating layer 110 and the semiconductor substrate 100 and may be connected to the first wiring patterns 115. The through silicon via TSV may have a pillar shape and may be disposed in the through silicon via region TSVR.

The through silicon vias TSV may be connected to the lower pads 150 provided on the second surface of the semiconductor substrate 100, respectively. The lower pads 150 may be connected to the upper pads 160 of another die through connection terminals (e.g., conductive bumps or solder balls).

The through silicon via TSV may include a barrier layer and a metal layer. The barrier layer may include a double layer such as titanium, titanium nitride, tantalum, tantalum nitride, ruthenium, cobalt, manganese, tungsten nitride, nickel, nickel boride, or titanium/titanium nitride, or a combination of double layers and other types. The barrier layer may reduce the diffusion of metal contained in the through silicon via TSV into the semiconductor substrate 100. The metal layer may include, for example, silver (Ag), gold (Au), copper (Cu), aluminum (Al), tungsten (W), or indium (In).

A sidewall insulating layer 101 may surround a sidewall of each of the through silicon vias TSV and may be interposed between the through silicon vias TSV and the semiconductor substrate 100. For example, the sidewall insulating layer 101 may include silicon oxide, silicon oxynitride, silicon nitride, or a combination thereof. The first wiring patterns 115 may be formed on the first interlayer insulating layer

110. The first wiring patterns 115 may be electrically connected to the first and second contact plugs 111 and 113 and the through silicon vias TSV.

A second interlayer insulating layer 120 may be disposed on the first interlayer insulating layer 110, and the second wiring patterns 125 may be disposed on the second interlayer insulating layer 120. The second wiring patterns 125 may electrically connect the first impurity region DR of each respective transistor PT and NT and the corresponding through silicon via TSV. For example, the second wiring pattern 125 may be electrically connected to the first impurity region DR and the corresponding through silicon via TSV.

As an example, the first impurity regions DR of the first transistor PT in the PMOS region PR and the second transistor NT in the NMOS region NR may be electrically connected to the through silicon via TSV, through the second wiring patterns 125.

The first and second wiring patterns 115 and 125 may formed of at least one metal or metal alloy selected from the group including, for example, tungsten (W), titanium (Ti), tantalum (Ta), copper (Cu), aluminum (Al), nickel (Ni), silver (Ag), gold (Au), platinum (Pt), tin (Sn), lead (Pb), chromium (Cr), palladium (Pd), indium (In), zinc (Zn), and carbon (C).

A third interlayer insulating layer 130 may be disposed on the second interlayer insulating layer 120, and the upper pads 160 may be disposed on the third interlayer insulating layer 130. For example, the upper pads 160 may be on the first surface of the semiconductor substrate 100, with the first, second, and third interlayer insulating layers 110, 120, and 130 therebetween. The upper pads 160 may be electrically connected to the first and second wiring patterns 115 and 125 and the through silicon vias TSV, through contact plugs. For example, the through silicon vias TSV may be electrically connected to the lower pads 150 and the upper pads 160.

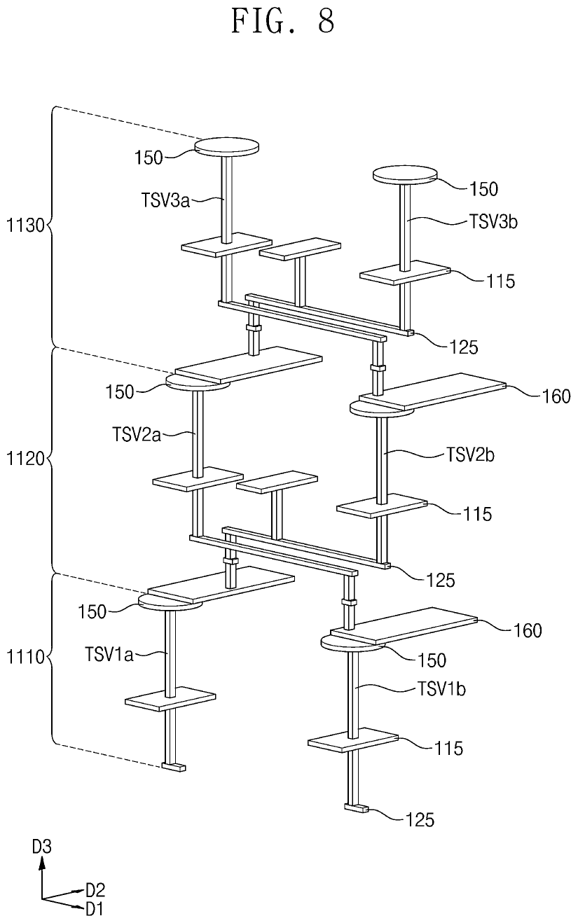

FIG. 8 is a diagram showing a portion of a semiconductor device according to embodiments of the inventive concepts.

Referring to FIG. 8, a semiconductor device may include vertically stacked buffer and core dies 1110, 1120, and 1130, as described above, and each die 1110, 1120, and 1130 may include through silicon vias TSV1a, TSV2a, TSV3a, TSV1b, TSV2b, and TSV3b in a TSV region TSVR.

According to embodiments, in the TSV region TSVR, each die 1110, 1120, and 1130 may include first channel through silicon vias TSV1a, TSV2a, and TSV3a and second channel through silicon vias TSV1b, TSV2b, and TSV3b.

In each of the dies 1110, 1120 and 1130, the first and second channel through silicon vias TSV1a, TSV2a, TSV3a, TSV1b, TSV2b, and TSV3b may be electrically connected to the lower and upper pads 150 and 160 through the wiring patterns 115 and 125.

The first channel through silicon via TSV1a of the buffer die 1110 may be connected to the first channel through silicon via TSV2a of the first core die 1120, and the first channel through silicon via TSV2a of the first core die 1120 may be connected to the first channel through silicon via TSV3a of the second core die 1130.

The second channel through silicon via TSV1b of the buffer die 1110 may be connected to the second channel through silicon via TSV2b of the first core die 1120, and the second channel through silicon via TSV2b of the first core die 1120 may be connected to the second channel through silicon via TSV3b of the second core die 1130.

The first channel through silicon via TSV2a of the first core die 1120 may be arranged to vertically overlap the first channel through silicon vias TSV1a and TSV3a of the buffer die 1110 and the second core die 1130, respectively. In other words, the first channel through silicon via TSV2a of the first core die 1120 may overlap the first channel through silicon vias TSV1a and TSV3a of the buffer die 1110 and the second core die 1130, respectively, in the third direction D3. The second channel through silicon via TSV2b of the first core die 1120 may be arranged to vertically overlap the second channel through silicon vias TSV1b and TSV3b of the buffer die 1110 and the second core die 1130, respectively. As used herein, “an element A overlaps an element B in a direction X” (or similar language) means that there is at least one straight line that extends in the direction X and intersects both the elements A and B.

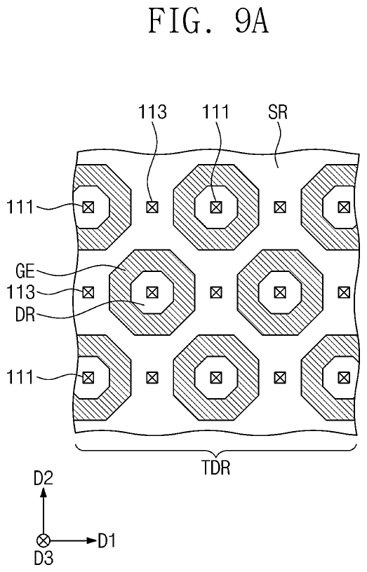

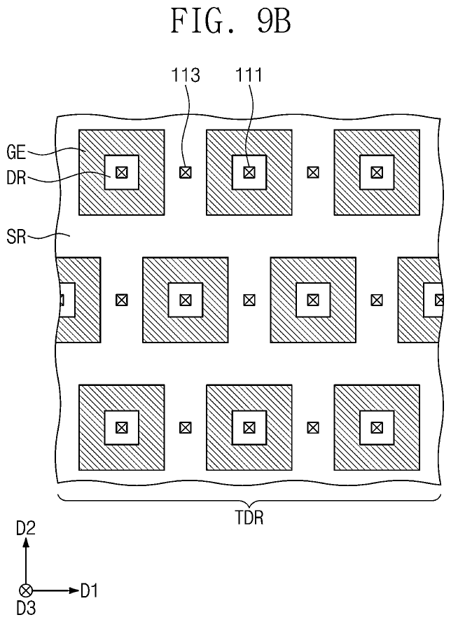

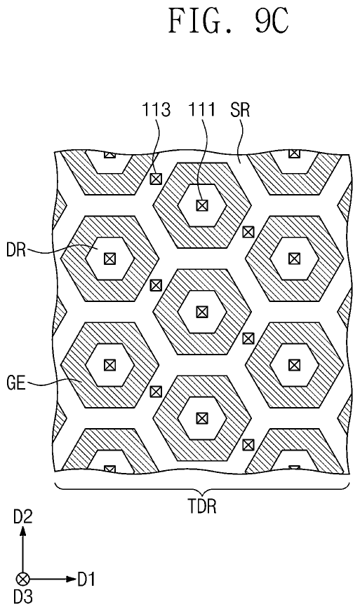

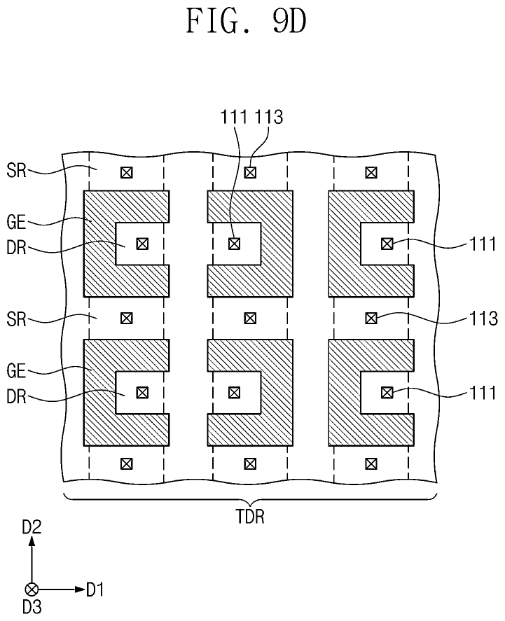

FIGS. 9A, 9B, 9C, and 9D are plan views showing a portion of a semiconductor device according to embodiments of the inventive concepts. For simplicity of explanation, descriptions of technical features that are the same as those of the previously described embodiments may be briefly described or omitted.

Referring to FIG. 9A, as described with reference to FIGS. 6A, 6B, and 7, the TSV driver provided on each die may include a plurality of transistors, and at least some of the plurality of transistors may include a gate electrode GE that has a closed curve shape.

The gate electrodes GE may be arranged on the semiconductor substrate 100 to be spaced apart from each other in the first direction D1 and the second direction D2 intersecting the first direction D1.

As an example, each gate electrode GE may have an octagonal donut shape (i.e., an octagonal ring shape) when viewed in a plan view. A first impurity region DR may be provided inside the octagonal donut-shaped gate electrode GE, and a second impurity region SR may be provided outside the gate electrode GE (e.g., when viewed in a plan view).

As another example, referring to FIG. 9B, each gate electrode GE may have a square ring shape when viewed in a plan view. As another example, referring to FIG. 9C, each gate electrode GE may have a hexagonal ring shape when viewed in a plan view.

As another example, referring to FIG. 9D, the gate electrode GE may have a partially open donut shape or a partially open curved shape when viewed in a plan view. That is, the gate electrode GE may surround a portion of the first impurity region DR when viewed in a plan view. For example, the gate electrode GE may have a ‘C’ shape when viewed in a plan view. The gate electrode GE may be disposed between the second impurity regions SR, and the first impurity region DR may be disposed inside the gate electrode GE (e.g., when viewed in a plan view).

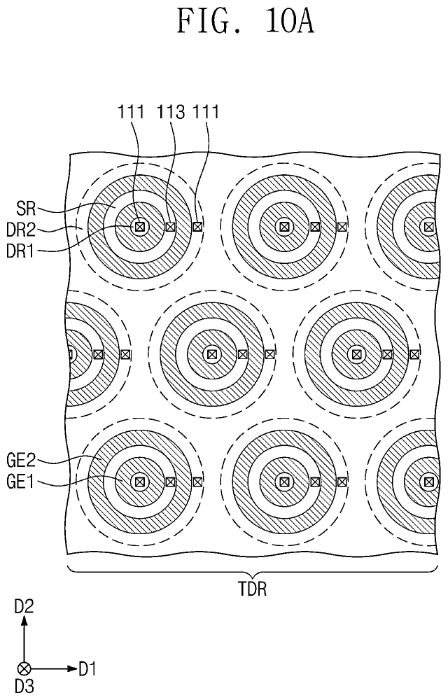

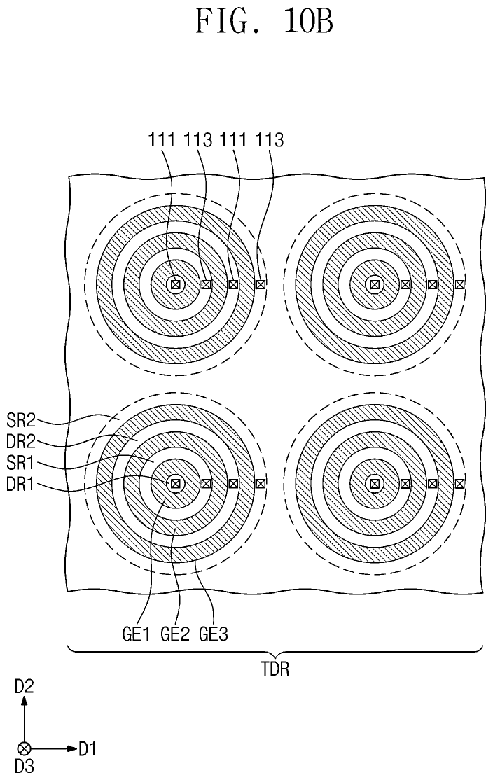

FIGS. 10A and 10B are plan views showing a portion of a semiconductor device according to embodiments of the inventive concepts. For simplicity of explanation, descriptions of technical features that are the same as those of the previously described embodiments may be briefly described or omitted.

Referring to FIG. 10A, as described with reference to FIGS. 6A, 6B, and 7, the TSV driver provided on each die may include a plurality of transistors, and at least some of the plurality of transistors may include a plurality of gate electrodes GE1 and GE2 having a closed curve shape.

In more detail, when viewed in a plan view, the second gate electrode GE2 having a closed curve shape may surround the first gate electrode GE1 having a closed curve shape. For example, each of the first and second gate electrodes GE1 and GE2 may have a ring donut shape, and a radius of the second gate electrode GE2 may be larger than a radius of the first gate electrode GE1. The first and second gate electrodes GE1 and GE2 may be electrically connected in common.

A first drain region DRI may be provided inside the first gate electrode GE1, and the first gate electrode GE1 may surround the first drain region DR1 (e.g., when viewed in a plan view). As described above, the first drain region DR1 may be connected to a through silicon via.

A source region SR may be provided between the outside of the first gate electrode GE1 and the inside of the second gate electrode GE2 (e.g., when viewed in a plan view). The source region SR may surround the first gate electrode GE1 (e.g., when viewed in a plan view). Additionally, a second drain region DR2 may be provided outside the second gate electrode GE2, and the second drain region DR2 may surround the second gate electrode GE2 (e.g., when viewed in a plan view).

Referring to FIG. 10B, at least one transistor constituting the TSV driver may include first, second, and third gate electrodes GE1, GE2, and GE3, first and second drain regions DR1 and DR2, and first and second source regions SR1 and SR2.

For example, each of the first, second, and third gate electrodes GE1, GE2, and GE3 may have a ring donut shape, a radius of the second gate electrode GE2 may be larger than a radius of the first gate electrode GE1, and a radius of the third gate electrode GE3 may be larger than a radius of the second gate electrode GE2. The first, second, and third gate electrodes GE1, GE2, and GE3 may be electrically connected in common.

A first drain region DRI may be provided inside the first gate electrode GE1, and the first gate electrode GE1 may surround the first drain region DR1 (e.g., when viewed in a plan view). As described above, the first drain region DR1 may be connected to a through silicon via.

A first source region SR1 may be provided between the outside of the first gate electrode GE1 and the inside of the second gate electrode GE2 (e.g., when viewed in a plan view). The first source region SR1 may surround the first gate electrode GE1 (e.g., when viewed in a plan view).

A second drain region DR2 may be provided between the outside of the second gate electrode GE2 and the inside of the third gate electrode GE3, and the second drain region DR2 may surround the second gate electrode GE2 (e.g., when viewed in a plan view). Additionally, a second source region SR2 may be provided outside the third gate electrode GE3, and the second source region SR2 may surround the third gate electrode GE3 (e.g., when viewed in a plan view).

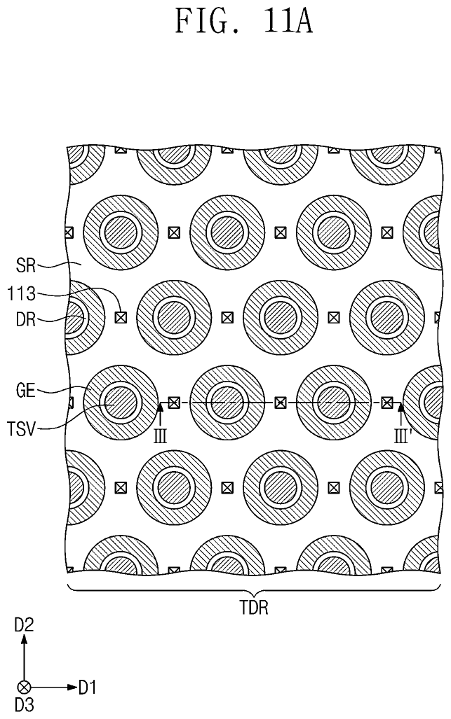

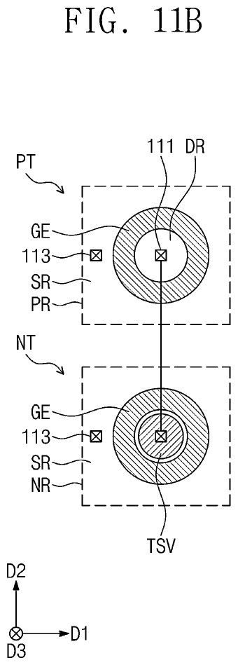

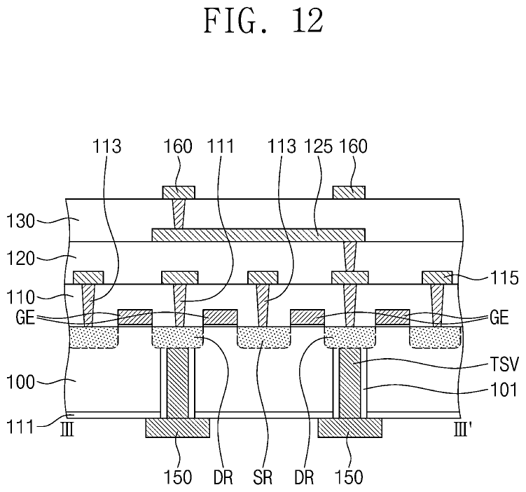

FIGS. 11A and 11B are plan views showing a portion of a semiconductor device according to embodiments of the inventive concepts. FIG. 12 is a cross-sectional view taken along line III-III′ of FIG. 11A. For simplicity of explanation, descriptions of technical features that are the same as those of the previously described embodiments may be briefly described or omitted.

Referring to FIGS. 11A, 11B, and 12, as previously described, a semiconductor device may include vertically stacked dies, and each die may include a semiconductor substrate 100, lower and upper pads 150 and 160, through silicon vias TSV, and a TSV driver. The TSV driver may include a plurality of transistors PT and NT, and at least some of the plurality of transistors PT and NT may include a closed curve-shaped gate electrode GE.

In embodiments, the transistors PT and NT and the through silicon vias TSV constituting the TSV driver may be provided in the driver circuit region TDR of the semiconductor substrate 100.

In more detail, in the driver circuit region TDR, the transistors PT and NT constituting the TSV driver may be integrated on the first surface of the semiconductor substrate 100. The driver circuit region TDR may include an NMOS region NR and a PMOS region PR.

Each of the transistors PT and NT may include a closed curve-shaped gate electrode GE, a first impurity region DR (or drain region), and a second impurity region SR (or source region). The gate electrode GE may have, for example, a ring shape, a hexagonal ring shape, an octagonal ring shape, or a square ring shape when viewed in a plan view.

The through silicon vias TSV may penetrate the semiconductor substrate 100 in the driver circuit region TDR and may be directly connected to the first impurity region DR. The through silicon via TSV may have a pillar shape. In embodiments, at least some of the gate electrodes GE may be arranged to surround the through silicon vias TSV, respectively, when viewed in a plan view. For example, at least some of the gate electrodes GE may have a closed loop shape when viewed in a plan view, and the through silicon vias TSV may be in the closed loop shape, respectively. The through silicon vias TSV may be connected to the lower pads 150 provided on the second surface of the semiconductor substrate 100, respectively.

The sidewall insulating layer 101 may surround the sidewall of each of the through silicon vias TSV and may be interposed between the through silicon vias TSV and the semiconductor substrate 100.

In embodiments, the first impurity region DR of the first transistor PT in the PMOS region PR constituting the TSV driver may be electrically connected to the first impurity region DR of the second transistor NT in the NMOS region NR and the corresponding through silicon via TSV through the first and second wiring patterns 115 and 125.

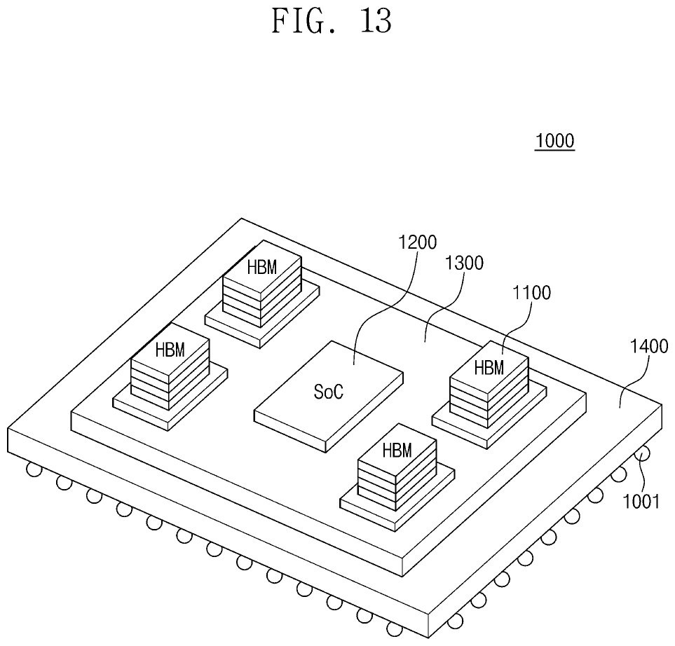

FIG. 13 is a diagram illustrating a semiconductor package including a semiconductor device according to embodiments of the inventive concepts.

Referring to FIG. 13, a semiconductor package 1000 may include a plurality of first semiconductor devices 1100, a second semiconductor device 1200, an interposer 1300, and a package substrate 1400.

The first semiconductor devices 1100 and the second semiconductor devices 1200 may be disposed on the interposer 1300. The interposer 1300 may be disposed on the package substrate 1400.

The semiconductor package 1000 may transmit and receive signals with other external packages or semiconductor devices through a solder ball 1001 attached to a lower portion of the package substrate 1400.

Each of the first semiconductor devices 1100 may be configured based on HBM standard. However, the inventive concepts are not limited thereto, and each of the first semiconductor devices 1100 may be configured based on GDDR (graphics double data rate), HMC, or Wide I/O standards. Each of the first semiconductor devices 1100 may be a semiconductor device 1100 according to the embodiments of the inventive concepts described above.

The second semiconductor device 1200 may include at least one processor and a plurality of memory controllers for controlling the plurality of first semiconductor devices 1100. For example, the second semiconductor device 1200 may include at least one of a central processing unit (CPU), an Application Processor (AP), a Graphics Processing Unit (GPU), a Neural Processing Unit (NPU), a tensor processing unit (TPU), a vision processing unit (VPU), an image signal processor (ISP), or a digital signal processor (DSP) to execute specialized operations. The second semiconductor device 1200 may transmit and receive signals with a corresponding semiconductor device through a memory controller.

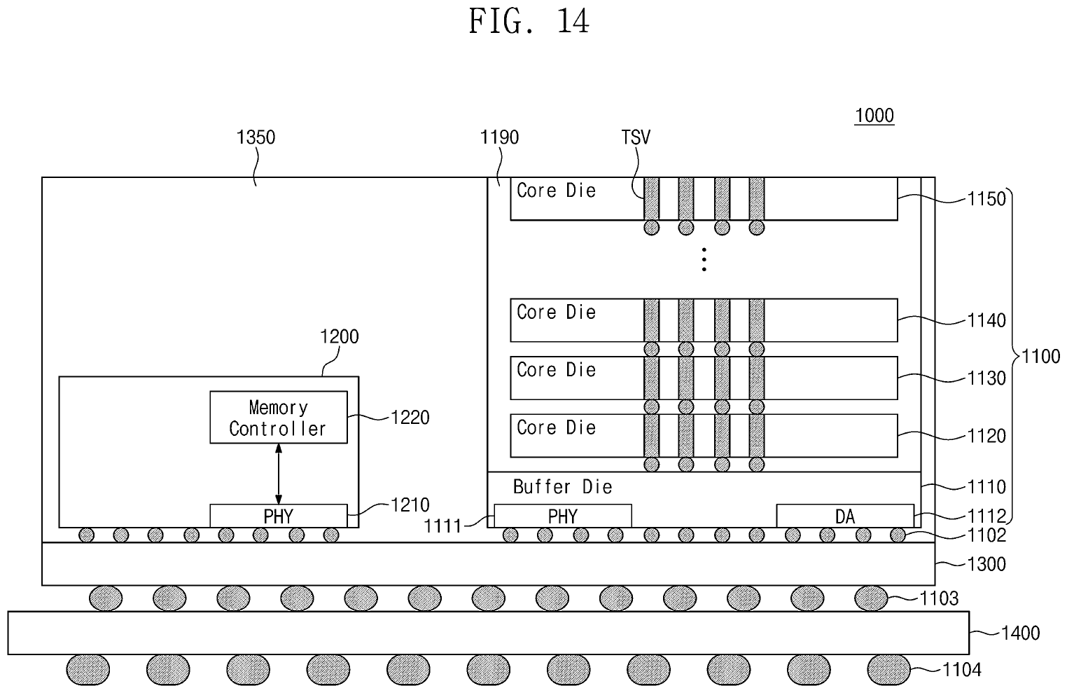

FIG. 14 is a cross-sectional view of a semiconductor package including a semiconductor device according to embodiments of the inventive concepts.

Referring to FIG. 14, a semiconductor package 1000 may include a first semiconductor device 1100, a second semiconductor device 1200, an interposer 1300, and a package substrate 1400. The first semiconductor device 1100 may be a semiconductor device according to the previously described embodiments. That is, the first semiconductor device 1100 may include a buffer die 1110 and core dies 1120 to 1150.

The buffer die 1110 and the core dies 1120 to 1150 may be electrically connected to each other through the through silicon vias TSV and bumps. The buffer die 1110 may receive signals provided to each channel from the second semiconductor device 1200 through bumps 1102 allocated for each channel. For example, the bumps 1102 may be micro bumps.

The second semiconductor device 1200 may execute applications supported by the semiconductor package 1000 using the first semiconductor device 1100. For example, the second semiconductor device 1200 may include at least one of a central processing unit (CPU), an Application Processor (AP), a Graphics Processing Unit (GPU), a Neural Processing Unit (NPU), a tensor processing unit (TPU), a vision processing unit (VPU), an image signal processor (ISP), or a digital signal processor (DSP) to execute specialized operations.

The second semiconductor device 1200 may include a physical layer 1210 and a memory controller 1220. The physical layer 1210 may include input/output circuits for transmitting and receiving signals to and from the physical layer PHY provided in the physical region 1111 of the first semiconductor device 1100. The second semiconductor device 1200 may provide various signals to the physical layer PHY of the first semiconductor device 1100 through the physical layer 1210. The signals provided to the physical layer PHY of the first semiconductor device 1100 may be transmitted to the core dies 1120 to 1150 through interface circuits and through silicon vias TSV of the physical layer PHY.

A memory controller 1220 may control the overall operation of the first semiconductor device 1100. The memory controller 1220 may transmit signals for controlling the first semiconductor device 1100 to the first semiconductor device 1100 through the physical layer 1210.

An interposer 1300 may connect the first semiconductor device 1100 and the second semiconductor device 1200. The interposer 1300 may connect the physical layer PHY of the first semiconductor device 1100 and the physical layer 1210 of the second semiconductor device 1200 and may provide physical paths formed using conductive materials.

Accordingly, the first semiconductor device 1100 and the second semiconductor device 1200 may be stacked on the interposer 1300 and may transmit and receive signals to each other.

Bumps 1103 may be attached to an upper portion of the package substrate 1400, and solder balls 1104 may be attached to a lower portion of the package substrate 1400. For example, the bumps 1103 may be flip-chip bumps. The interposer 1300 may be stacked on the package substrate 1400, with the bumps 1103 therebetween. The semiconductor package 1000 may transmit and receive signals with other external packages or semiconductor devices through the solder balls 1104. For example, the package substrate 1400 may be a printed circuit board (PCB).

A package substrate 1400 may be, for example, a printed circuit board, a flexible substrate, or a tape substrate. As an example, the package substrate 1400 may be a flexible printed circuit board with internal wirings formed therein, a rigid printed circuit board, or a combination thereof.

The first semiconductor device 1100 may further include a molding layer 1190 on (e.g., covering) side surfaces of the core dies 1120 to 1150. The molding layer 1190 may include, for example, an epoxy mold compound (EMC).

The semiconductor package 1000 may further include a package molding layer 1350 disposed on the interposer 1300 and molding the first semiconductor device 1100 and the second semiconductor device 1200.

The package molding layer 1350 may include, for example, an epoxy mold compound (EMC). In embodiments, the package molding layer 1350 may be on (e.g., may cover) an upper surface of the interposer 1300, a side surface of the first semiconductor device 1100, and a side surface of the second semiconductor device 1200, but may not be on an upper surface of the first semiconductor device 1100.

According to embodiments of the inventive concepts, some of the transistors constituting the TSV driver included in each die may be configured as the transistor including the gate electrode that has a closed curve shape. Accordingly, the area of the region where the TSV driver is provided may be reduced, and the transistors may be integrated with the limited area even when the number of through silicon vias increases.

As the transistors connected to the through silicon vias include the gate electrodes having the closed curve shape, the input capacitance of the through silicon vias may be reduced. Therefore, the integration of the semiconductor device including vertically stacked dies may be improved, and signal transmission characteristics and operating characteristics may be improved.

While example embodiments are described above, a person skilled in the art will understand that many modifications and variations can be made without departing from the scope of the claims. Accordingly, the example embodiments of the inventive concepts should be considered in all respects as illustrative and not restrictive, with the scope of the inventive concepts being indicated by the appended claims.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. In addition, it will be understood that, although the terms “first”, “second”, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure.

What is claimed is:

1. A semiconductor device comprising:
a plurality of vertically stacked dies, each of the dies comprising:
a semiconductor substrate;
upper pads on an upper surface of the semiconductor substrate;
lower pads on a lower surface of the semiconductor substrate;
through silicon vias extending in the semiconductor substrate and electrically connected to the upper pads and the lower pads; and
a through silicon via (TSV) driver on the semiconductor substrate and configured to control the through silicon vias,
wherein the TSV driver includes at least one transistor comprising a gate electrode that has a closed loop shape when viewed in a plan view.

2. The semiconductor device of claim 1, wherein the at least one transistor further comprises:
a first impurity region in the semiconductor substrate and surrounded by the gate electrode when viewed in a plan view; and
a second impurity region in the semiconductor substrate and surrounding the gate electrode when viewed in a plan view.

3. The semiconductor device of claim 2, wherein an area of the second impurity region is larger than an area of the first impurity region.

4. The semiconductor device of claim 2, further comprising a conductive line electrically connected to the first impurity region and one of the through silicon vias.

5. The semiconductor device of claim 1, wherein the gate electrode has a ring shape, a hexagonal ring shape, an octagonal ring shape, or a square ring shape when viewed in a plan view.

6. The semiconductor device of claim 1, wherein the at least one transistor includes a plurality of transistors comprising a plurality of gate electrodes, respectively, and
wherein the gate electrodes of the transistors are spaced apart from each other and are arranged two-dimensionally.

7. The semiconductor device of claim 6, wherein respective ones of the transistors further comprise:
a first impurity region in the semiconductor substrate and surrounded by a respective one of the gate electrodes when viewed in a plan view; and
a second impurity region in the semiconductor substrate and between adjacent ones of the gate electrodes.

8. The semiconductor device of claim 1, wherein the gate electrode surrounds a respective one of the through silicon vias when viewed in a plan view.

9. The semiconductor device of claim 1, wherein the semiconductor substrate includes an NMOS region and a PMOS region,
wherein the at least one transistor includes a first transistor on the NMOS region and a second transistor on the PMOS region, and
wherein at least one of the first transistor or the second transistor comprises the gate electrode, and the gate electrode surrounds a respective one of the through silicon vias when viewed in a plan view.

10. A semiconductor device comprising:
a plurality of vertically stacked dies, each of the dies comprising:
a semiconductor substrate;
upper pads on an upper surface of the semiconductor substrate;
lower pads on a lower surface of the semiconductor substrate;
through silicon vias extending in the semiconductor substrate and electrically connected to the upper pads and the lower pads; and
a through silicon via (TSV) driver on the semiconductor substrate and configured to control the through silicon vias,
wherein the TSV driver includes a transistor comprising a first gate electrode and a second gate electrode that each have a closed loop shape when viewed in a plan view, and
wherein the second gate electrode surrounds the first gate electrode when viewed in a plan view.

11. The semiconductor device of claim 10, further comprising:
a first drain region in the semiconductor substrate, wherein the first drain region is surrounded by the first gate electrode when viewed in a plan view;
a source region in the semiconductor substrate, wherein the source region is between the first gate electrode and the second gate electrode when viewed in a plan view; and
a second drain region in the semiconductor substrate, wherein the second drain region surrounds the second gate electrode when viewed in a plan view.

12. The semiconductor device of claim 11, wherein one of the through silicon vias is electrically connected to the first drain region.

13. The semiconductor device of claim 11, wherein the semiconductor substrate includes a driver circuit region and a TSV region,
wherein the through silicon vias are on the TSV region,
wherein the first and second gate electrodes, the first and second drain regions, and the source region are on the driver circuit region.

14. The semiconductor device of claim 10, wherein the first and second gate electrodes are electrically connected in common.

15. A semiconductor device comprising:
a buffer die including first through silicon vias and first through silicon via (TSV) drivers that are configured to control the first through silicon vias; and
a plurality of core dies vertically stacked on the buffer die, each of the core dies including second through silicon vias electrically connected to the first through silicon vias and second TSV drivers configured to control the second through silicon vias,
wherein each of the first and second TSV drivers includes a plurality of transistors each comprising a gate electrode that has a closed loop shape when viewed in a plan view.

16. The semiconductor device of claim 15, wherein each of the transistors further comprises:
a first impurity region in a semiconductor substrate and surrounded by the gate electrode when viewed in a plan view; and
a second impurity region in the semiconductor substrate and surrounding the gate electrode when viewed in a plan view.

17. The semiconductor device of claim 16, wherein each of the first and second through silicon vias is electrically connected to the first impurity region of a respective one of the transistors.

18. The semiconductor device of claim 15, wherein the buffer die and each of the core dies includes a driver circuit region and a TSV region,
wherein the first and second TSV drivers are in the driver circuit region, and
wherein the first and second through silicon vias are in the TSV region.

19. The semiconductor device of claim 15, wherein a respective one of the first through silicon vias is surrounded by the gate electrode of a first respective one of the transistors when viewed in a plan view, and
wherein a respective one of the second through silicon vias is surrounded by the gate electrode of a second respective one of the transistors when viewed in a plan view.

20. The semiconductor device of claim 15, wherein the gate electrode includes a first gate electrode having a closed loop shape when viewed in a plan view, and a second gate electrode having a closed loop shape and surrounding the first gate electrode when viewed in a plan view.
